(19) United States
(12) Patent Application Publication
(10) Pub. No.: US 2026/0186088 A1
(43) Pub. Date: Jul. 2, 2026

(54) GRADIENT COILS FOR MAGNETIC RESONANCE DEVICES AND MONITORING SYSTEMS AND METHODS OF GRADIENT COILS

(71) Applicant: SHANGHAI UNITED IMAGING HEALTHCARE ADVANCED TECHNOLOGY RESEARCH INSTITUTE CO., LTD., Shanghai (CN)

(72) Inventors: Zhuming SHUAI, Shanghai (CN); Zijun ZHANG, Shanghai (CN); Rong ZHONG, Shanghai (CN)

(73) Assignee: SHANGHAI UNITED IMAGING HEALTHCARE ADVANCED TECHNOLOGY RESEARCH INSTITUTE CO., LTD., Shanghai (CN)

(21) Appl. No.: 19/435,690

(22) Filed: Dec. 29, 2025

(30) Foreign Application Priority Data
Dec. 27, 2024 (CN) 202411958978.9

(51) Int. Cl. G01R 33/385; G01D 21/02

(52) U.S. Cl. CPC G01R 33/385; G01D 21/02

(57) ABSTRACT

Provided is a gradient coil for a magnetic resonance device. The gradient coil for the magnetic resonance device includes a gradient coil body and at least one sensor group. Each of the at least one sensor group is disposed at a predetermined position on the gradient coil body. Each sensor group includes a strain sensor configured to detect a strain signal at the predetermined position and a temperature sensor configured to detect a temperature signal at the predetermined position.

### CROSS-REFERENCE TO RELATED APPLICATIONS

This application claims priority to the Chinese Patent Application No. 202411958978.9, filed on Dec. 27, 2024, the contents of which are hereby incorporated by reference.

### TECHNICAL FIELD

The present disclosure relates to the field of magnetic resonance devices, and in particular, to gradient coils for magnetic resonance devices, and monitoring systems and methods of gradient coils.

### BACKGROUND

When a magnetic resonance device performs imaging, a gradient coil is configured to generate an alternating magnetic field along different directions. The magnetic field is excited by an alternating current signal e.g., a sequence signal) introduced into the gradient coil. The gradient coil is typically solenoid coil placed at a center of a magnet. When the alternating current is introduced to the gradient coil, the gradient coil is subjected to an alternating Lorentz force. The alternating Lorentz force not only causes the gradient coil to vibrate and deform, but also continuously applies alternating loads to the gradient coil during operation. The alternating loads lead to safety issues of the gradient coil, such as static failure, fatigue failure, thermal fatigue, etc. Therefore, it is necessary to detect a strain of the gradient coil to provide important data support for reliability judgment, fatigue life prediction of the gradient coil, and evaluation of the correctness of simulation calculations during the subsequent service process of the gradient coil of the magnetic resonance device. However, existing manners for strain detection are usually inaccurate

Therefore, there is an urgent need for a gradient coil capable of detecting strain and monitoring systems and methods for the gradient coil.

### SUMMARY

One or more embodiments of the present disclosure provide a gradient coil for a magnetic resonance device. The gradient coil for the magnetic resonance device includes a gradient coil body and at least one sensor group. Each of the at least one sensor group is disposed at a predetermined position on the gradient coil body. Each sensor group includes a strain sensor configured to detect a strain signal at the predetermined position and a temperature sensor configured to detect a temperature signal at the predetermined position.

One or more embodiments of the present disclosure provide a monitoring system for a magnetic resonance gradient coil. The monitoring system for the magnetic resonance gradient coil includes at least one fiber grating sensor and a fiber grating demodulator. Each fiber grating sensor is disposed at a predetermined position on a gradient coil body. The fiber grating demodulator is connected to the at least one fiber grating sensor via optical fibers, and configured to determine a variation of a physical quantity of the gradient coil body at the predetermined position based on a detected signal of the at least one fiber grating sensor.

One or more embodiments of the present disclosure provide a monitoring method for a magnetic resonance gradient coil. The monitoring method includes obtaining, from a temperature sensor disposed at a predetermined position on a gradient coil body, a temperature signal; obtaining, from a strain sensor disposed at the predetermined position on the gradient coil body, a strain signal; and determining a strain of the gradient coil body at the predetermined position based on the strain signal and the temperature signal.

One or more embodiments of the present disclosure provide a monitoring device for a magnetic resonance gradient coil. The monitoring device includes an acquiring module and a determining module. The acquiring module is configured to obtain, from a temperature sensor disposed at a predetermined position on a gradient coil body, a temperature signal and obtain, from a strain sensor disposed at the predetermined position on the gradient coil body, a strain signal. The determining module is configured to determine a strain of the gradient coil body at the predetermined position based on the strain signal and the temperature signal.

One or more embodiments of the present disclosure provide an electronic device. The electronic device includes at least one storage device including a set of instructions, and at least one processor in communication with the at least one storage device. When executing the set of instructions, the at least one processor is directed to cause the electronic device to perform the monitoring method.

### BRIEF DESCRIPTION OF THE DRAWINGS

The present disclosure will be further illustrated by way of exemplary embodiments, which will be described in detail through the accompanying drawings. These embodiments are not limiting, and in these embodiments, the same reference numerals denote the same structures.

FIG. 1 is a structural schematic diagram of a gradient coil for a magnetic resonance device according to some embodiments of the present disclosure;

FIG. 2 is a layout schematic diagram of a strain sensor of a sensor group according to some embodiments of the present disclosure;

FIG. 3 is an encapsulation schematic diagram of a non-metallic encapsulation device according to some embodiments of the present disclosure;

FIG. 4 is a structural schematic diagram of a monitoring system for a magnetic resonance gradient coil according to some embodiments of the present disclosure;

FIG. 5 is an exemplary flowchart of a monitoring method for a magnetic resonance gradient coil according to some embodiments of the present disclosure;

FIG. 6 is a structural schematic diagram of a monitoring device for a magnetic resonance gradient coil according to some embodiments of the present disclosure; and

FIG. 7 is a structural schematic diagram of an electronic device according to some embodiments of the present disclosure.

### DETAILED DESCRIPTION

To more clearly illustrate the technical solutions of the embodiments of the present disclosure, a brief introduction will be made to the accompanying drawings used in the description of the embodiments. Obviously, the drawings in the following description are only some examples or embodiments of the present disclosure, and for those of ordinary skill in the art, without creative labor, the present disclosure may be applied to other similar scenarios based on these drawings. Unless obvious from the context or otherwise stated, the same reference numerals in the drawings denote the same structures or operations.

It should be understood that the terms “system,” “device,” “unit,” and/or “module” used herein are a manner for distinguishing different components, elements, parts, sections, or assemblies of different levels. However, if other words may achieve the same purpose, the words may be replaced by other expressions.

As shown in the present disclosure and the claims, unless the context clearly indicates an exception, the words “a,” “an,” “one,” and/or “the” are not specifically limited to singular and may also include plural. Generally, the terms “comprise,” and “include” only indicate including explicitly identified steps and elements; these steps and elements do not constitute an exclusive list, and the manner or device may also contain other steps or elements.

The present disclosure uses flowcharts to illustrate the operations performed by the system according to the embodiments of the present disclosure. It should be understood that the preceding or following operations are not necessarily performed precisely in sequence. Instead, the steps may be processed in reverse order or simultaneously. At the same time, other operations may be added to these processes, or one or several operations may be removed from these processes.

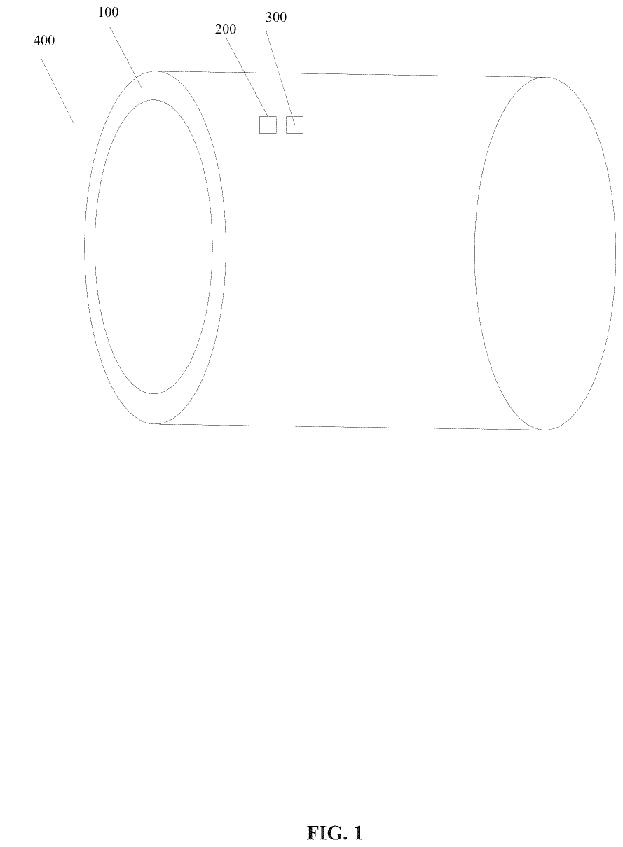

FIG. 1 is a structural schematic diagram of a gradient coil for a magnetic resonance device according to some embodiments of the present disclosure.

In some embodiments, a gradient coil for a magnetic resonance device includes a gradient coil body and at least one sensor group. As shown in FIG. 1 (FIG. 1 only shows one sensor group as an example), the gradient coil includes a gradient coil body 100 and at least one sensor group. Each of the at least one sensor group is disposed at a predetermined position on the gradient coil body 100. Each sensor group includes a strain sensor 200 configured to detect a strain signal at the predetermined position and a temperature sensor 300 configured to detect a temperature signal at the predetermined position.

The gradient coil body 100 is an electromagnetic device including a plurality of conductive coils.

In some embodiments, the gradient coil body 100 is an important component in a magnetic resonance imaging system. The the gradient coil body 100 is configured to generate a spatially varying magnetic field to achieve signal acquisition and imaging at different positions.

In some embodiments, a material of the gradient coil body 100 includes epoxy resin. Complex structures, such as a coil, a water pipe, etc., are disposed inside the epoxy resin. The coil is disposed in a geometric shape formed by the epoxy resin. In some embodiments, the coil may be a copper coil, and the coil is rapidly energized during a magnetic resonance imaging process to generate the required varying magnetic field.

The sensor group refers to a combination of a plurality of sensors.

In some embodiments, each sensor group includes at least one strain sensor 200 and at least one temperature sensor 300.

A strain sensor 200 refers to a sensor that measures a strain on a surface of an object or a strain inside a structure. In some embodiments, the strain sensor 200 is disposed at the predetermined position to detect a strain signal at the predetermined position.

The strain signal refers to a signal indicating deformation of an object or material under external actions (such as tension, compression, torsion, etc.) and/or temperature actions. In some embodiments, the strain signal is collected by the strain sensor 200 under a combined influence of temperature actions and strain actions.

The temperature sensor 300 refers to a device for detecting and measuring a temperature of an object or environment. In some embodiments, the temperature sensor 300 is configured to detect a temperature signal at the predetermined position.

The temperature signal refers to a signal related to the temperature of the measured object or environment. In some embodiments, the temperature signal is collected by the temperature sensor 300 under the influence of temperature actions.

In some embodiments, the temperature signal is configured to correct or compensate the strain signal. For this part, refer to the relevant description below.

The gradient coil undergoes special environments such as vacuum and high temperature during a curing process. The gradient coil works in high magnetic fields and alternating electric fields. In some embodiments, for high-precision monitoring in the magnetic resonance imaging device, the strain sensor 200 or the temperature sensor 300 is a fiber grating sensor. For example, the strain sensor 200 is a fiber Bragg grating strain sensor, and the temperature sensor 300 is a fiber Bragg grating temperature sensor.

The fiber grating sensor is a sensor based on optical fiber technology, which uses a grating structure in an optical fiber to modulate a wavelength of light, thereby achieving measurement of physical quantities.

In some embodiments, when an external physical quantity (such as a strain, a temperature, a vibration or an acceleration, etc.) changes, a refractive index or a grating pitch of the fiber grating sensor also changes, thereby causing a central wavelength offset of the reflected light. There is a certain relationship between an offset of the central wavelength and a change in an external physical quantity, so by measuring the offset of the central wavelength, the change in the external physical quantity may be indirectly measured.

When the gradient coil body 100 is subjected to an external force, the strain is generated. The strain causes a change in a grating pitch of the fiber Bragg grating strain sensor, thereby causing the central wavelength offset of the reflected light. The offset (e.g., a second central wavelength offset) has a certain relationship with a strain value, so by measuring the offset, the strain signal may be obtained.

When a temperature of the gradient coil body 100 or the surrounding environment of the gradient coil body 100 changes, thermal expansion or thermo-optic effect of the fiber Bragg gratin temperature sensor 30 is generated, thereby causing the central wavelength offset of the reflected light. The offset (e.g., a first central wavelength offset) also has a certain relationship with a temperature change value, so by measuring the offset, the temperature signal may be obtained.

Therefore, the temperature signal includes the first central wavelength offset, and the strain signal includes the second central wavelength offset. For this part, and the description of how the fiber grating sensor collects the temperature signal and the strain signal, refer to the relevant description below.

In some embodiments, the strain of the gradient coil is mainly in a circumferential direction and an axial direction of the gradient coil, and the fiber grating sensor detects directionally strain along a length direction of an optical fiber within. Therefore, the arrangement of the fiber grating sensors is strictly in the axial direction and the circumferential direction of the gradient coil to ensure accurate detection.

In some embodiments, the strain sensor 200 of each of the at least one sensor group is arranged along an axial direction of the gradient coil.

The axial direction refers to a length direction of the gradient coil body 100, and is parallel to a central axis of the gradient coil body 100.

In some embodiments, the strain sensor 200 may be arranged along the axial direction of the gradient coil body 100, and the temperature sensor 300 of the same sensor group as the strain sensor 200 is arranged adjacent to the strain sensor 200 to monitor a strain in the axial direction of the gradient coil body 100 and a temperature change at the corresponding position.

For the strain sensor 200 and the temperature sensor 300 in the same sensor group, a distance between the strain sensor 200 and the temperature sensor 300 on the gradient coil body 100 is less than a distance threshold. The distance threshold may be predetermined. By setting the distance threshold, a sensor group is enabled to detect a strain signal and a temperature signal at a predetermined position accurately.

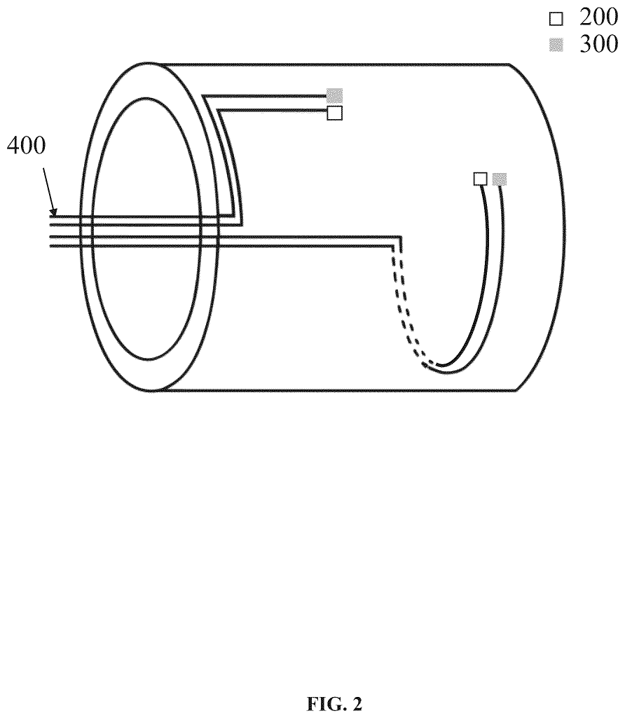

FIG. 2 is a layout schematic diagram of a strain sensor of a sensor group according to some embodiments of the present disclosure.

In some embodiments, as shown in FIG. 2, the strain sensor 200 of each of the at least one sensor group is arranged along a circumferential direction of the gradient coil.

The circumferential direction refers to a circumferential direction of the gradient coil body 100, and the circumferential direction is perpendicular to the axial direction.

In some embodiments, the strain sensor 200 may be arranged along the circumferential direction of the gradient coil body 100, and the temperature sensor 300 of the same sensor group as the strain sensor 200 is arranged adjacent to the strain sensor 200 to monitor a strain in the circumferential direction of the gradient coil body 100 and the temperature change at the corresponding position.

In some embodiments of the present disclosure, by arranging the strain sensor 200 in the axial direction and the circumferential direction, the strain at the position where the strain sensor 200 is located can be accurately detected.

In some embodiments, the sensor group is mainly arranged at positions with large strain gradients and large temperature gradients. For different products, a count, an arrangement manner, and an arrangement position of the sensor group may vary to meet different monitoring needs.

In some embodiments, the at least one sensor group may be one or more. For example, if there are N sensor groups, then N groups of sensors are disposed at N predetermined positions on the gradient coil body 100, and each sensor group corresponds to one predetermined position on the gradient coil body 100. That is, one sensor group is configured to detect a temperature signal and a strain signal at one predetermined position.

The predetermined position refers to a pre-set or planned installation position of each sensor group.

In some embodiments, the predetermined position may be a position that is configured to detect the strain in the circumferential direction of the gradient coil body 100 and/or a position that is configured to detect the strain in the axial direction of the gradient coil body 100. For example, the predetermined position may include a predetermined position in the circumferential direction of the gradient coil body 100 and/or a predetermined position in the axial direction of the gradient coil body 100. By setting the sensor group at the predetermined position in the circumferential direction, the strain change in the circumferential direction of the gradient coil and the temperature change may be monitored. By setting the sensor group at the predetermined position in the axial direction, the strain change in the axial direction of the gradient coil and the temperature change may be monitored.

In some embodiments, the predetermined position may be a position with a large strain change and a large temperature change. The predetermined position may be determined by a structure of the gradient coil and a finite element simulation manner. After determining the predetermined position, each sensor group may be pre-embedded at the predetermined position during the manufacturing of the gradient coil.

Specifically, in some embodiments, the predetermined position may be a position on the gradient coil where a strain gradient and/or a temperature gradient meets a predetermined condition.

The strain gradient refers to a vector quantity that represents aa spatial rate of change of the strain. A high strain gradient exists where there is a sharp change in deformation over a short distance. The temperature gradient refers to a vector quantity measuring how rapidly the temperature changes from one point to another in a space. A high temperature gradient indicates a steep and rapid change in temperature over a small distance.

In some embodiments, the finite element simulation manner is configured to determine the strain gradient and/or the temperature gradient at various positions of the gradient coil. Exemplarily, a process of the finite element simulation manner includes establishing a three-dimensional finite element model of the gradient coil, solving the three-dimensional finite element model to obtain strain values and temperature values at various positions on the gradient coil, performing spatial difference processing on the simulation results of adjacent positions along the circumferential direction and/or the axial direction of the gradient coil to calculate the strain gradient and/or temperature gradient at each position, and screening out the predetermined positions that meet the predetermined condition from all simulation positions according to the predetermined condition.

In some embodiments of the present disclosure, the finite element simulation manner may simultaneously simulate the mechanical, thermal, and electromagnetic influences on the gradient coil during operation, thereby obtaining actual strain and actual temperature.

In some embodiments, the predetermined condition may be determined according to design requirements or performance requirements to ensure that the strain change (also referred to as the strain gradient) or the temperature change (also referred to as the temperature gradient) of the gradient coil is effectively monitored. The predetermined condition may be the top N positions sorted from largest to smallest by the strain gradient and/or the temperature gradient.

In some embodiments of the present disclosure, by using the positions on the gradient coil where the strain gradient and/or the temperature gradient meets the predetermined condition as the predetermined positions for installing a sensor group, the strain change and the temperature change generated by the gradient coil during operation is accurately measured.

In some embodiments, the strain sensor 200 and the temperature sensor 300 of each of the at least one sensor group are embedded at the predetermined position and integrated with the gradient coil body 100 within an epoxy resin.

The epoxy resin is a synthetic resin with excellent adhesion, corrosion resistance, and mechanical strength. In some embodiments, the epoxy resin is formed by the reaction of epoxy groups and a hardener, and after curing, a sturdy material that may withstand high temperatures and high stress is formed.

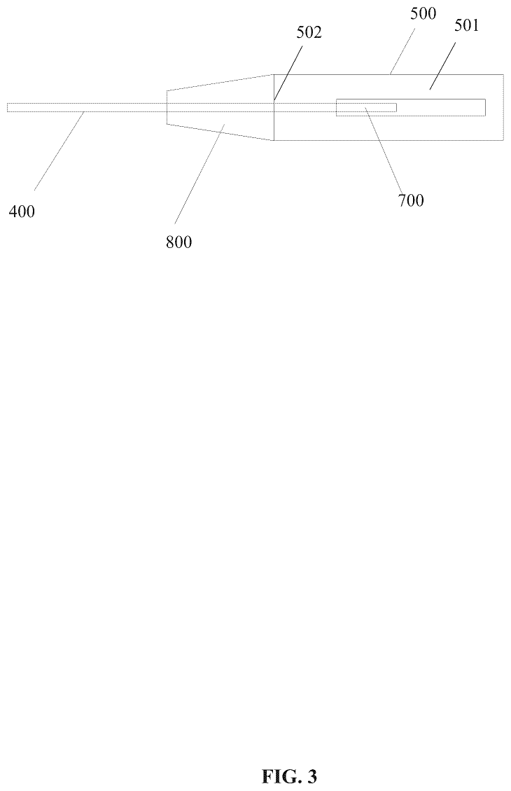

In some embodiments, the strain sensor 200 (e.g., the fiber Bragg grating strain sensor) is directly embedded inside the epoxy resin, while the temperature sensor 300 (e.g., the fiber Bragg grating temperature sensor) may be embedded inside the epoxy resin after being encapsulated by a non-metallic encapsulation device. When embedding the temperature sensor 300, special encapsulation treatment is required for the embedded fiber grating sensor to avoid damage during the embedding process. For more content on the non-metallic encapsulation device, refer to FIG. 3 and its related description.

In some embodiments, by embedding the sensors (including the strain sensor 200 and the temperature sensor 300) into the gradient coil body 100 and integrating the sensors into with the gradient coil body 100 within the epoxy resin, not only damage to the sensors is effectively avoided, but also the internal space of the magnetic resonance device is saved. This integrated design improves the reliability and stability of the magnetic resonance imaging system, while optimizing the space layout, enabling the sensors to work normally in a limited space, and improving the overall performance of the magnetic resonance device.

In some embodiments, the strain sensor 200 and the temperature sensor 300 of each of the at least one sensor group are disposed on a same optical fiber. As shown in FIG. 1, the strain sensor 200 (e.g., the fiber Bragg grating strain sensor) and the temperature sensor 300 (e.g., the fiber Bragg grating temperature sensor) are connected to a same optical fiber 400.

The optical fiber refers to an elongated transmission medium made of transparent material (such as glass or plastic) that transmits light signals through a principle of total reflection.

In some embodiments, the strain sensor 200 and the temperature sensor 300 of each of the at least one sensor group are disposed on the same optical fiber.

In some embodiments, each sensor group is connected to one optical fiber, and the strain sensor 200 and the temperature sensor 300 of each of the at least one sensor group are connected in series on the same optical fiber. A plurality of sensor groups are connected in parallel through a plurality of optical fibers (the light signals transmitted from the plurality of optical fibers do not interfere with each other).

In some embodiments, based on the size and the structure of the gradient coil, different types of fiber grating sensors may be customized to simultaneously achieve the temperature signal and the strain signal acquisition on the same optical fiber.

In some embodiments of the present disclosure, by disposing the strain sensor 200 and the temperature sensor 300 of each of the at least one sensor group on the same optical fiber, not only the wiring is simplified, but also simultaneous acquisition of the strain signal and the temperature signal at a single predetermined position is achieved. At the same time, the plurality of sensor groups are connected in parallel with each other, which can ensure that when any optical fiber or any sensor on any optical fiber is damaged, the normal operation of sensors on other optical fibers is not affected.

In some embodiments, the strain sensor 200 and the temperature sensor 300 of each of the at least one sensor group are disposed on different optical fibers.

In some embodiments, the strain sensor 200 and the temperature sensor 300 of each of the at least one sensor group are respectively connected to one optical fiber. That is, the strain sensor 200 and the temperature sensor 300 of each of the at least one sensor group are connected in parallel through independent optical fibers.

In some embodiments of the present disclosure, by disposing the strain sensor 200 and the temperature sensor 300 of each of the at least one sensor group on the different optical fibers, simultaneous acquisition of temperature and strain at the same predetermined position can also be achieved. At the same time, the plurality of sensors are connected in parallel with each other, which can ensure that when any optical fiber or any sensor on any optical fiber is damaged, the normal operation of sensors on other optical fibers is not affected.

In some embodiments, the gradient coil further includes optical fibers connected to each of the at least one sensor group. One end of each optical fiber is connected to the sensor group and the other end of each optical fiber is connected to a fiber grating demodulator.

The fiber grating demodulator refers to a device for regulating and analyzing light signals transmitted through the optical fiber. In some embodiments, the fiber grating demodulator emits light waves covering a specific band to the fiber grating sensor. When the fiber grating sensor is subjected to external actions such as strain or temperature, the central wavelength of the reflected light shifts, and the reflected light is returned along the optical fiber to the fiber grating demodulator. In some embodiments, the fiber grating demodulator may calculate a change value of strain and a change value of temperature based on a central wavelength offset of the reflected light.

In some embodiments of the present disclosure, when the strain sensor 200 and the temperature sensor 300 of each of the at least one sensor group are disposed on the same optical fiber, the strain sensor 200 and the temperature sensor 300 are connected to the fiber grating demodulator through one optical fiber, which can simplify wiring and centrally process data from a plurality of sensors.

In some embodiments of the present disclosure, when the strain sensor 200 and the temperature sensor 300 of each of the at least one sensor group are disposed on different optical fibers, the strain sensor 200 and the temperature sensor 300 are respectively connected to the fiber grating demodulator through independent optical fibers, so that the two sensors are independent of each other in signal transmission and do not interfere with each other. When one sensor fails or is maintained, the normal operation of the other sensor is not affected, thereby improving the reliability and flexibility of the magnetic resonance system.

In some embodiments, the gradient coil further includes an acceleration sensor configured to detect vibrations of the gradient coil.

The acceleration sensor refers to a sensor for measuring an acceleration of an object.

In some embodiments, the acceleration sensor is configured to monitor a vibration state of the gradient coil during operation. For example, a frequency response curve of the gradient coil is measured by the acceleration sensor, and changes in the frequency response curve are detected to identify whether the gradient coil has abnormal vibration or structural deformation. When the gradient coil deforms due to fatigue, loosening, or external force, vibration characteristics of the gradient coil will manifest as amplitude changes, resonance peak shifts, or new frequency components in the frequency response curve, thereby providing a basis for judging whether the gradient coil has potential structural abnormalities.

In some embodiments of the present disclosure, by setting the acceleration sensor in the gradient coil, the vibration state of the gradient coil is monitored in real time. Further, by combining data from a plurality of types of sensors such as the strain sensor 200 and the temperature sensor 300, machine learning algorithms is configured to perform real-time analysis and long-term trend evaluation of the operating state of the gradient coil. Through the fusion of multi-source data and the identification of feature changes, abnormal conditions of the gradient coil can be more accurately determined, achieving early warning of potential faults such as structural loosening, fatigue deformation, or abnormal stress, thereby improving the safety and reliability of the gradient coil operation.

In some embodiments, the temperature sensor 300 and the strain sensor 200 of each of the at least one sensor group are located at a radially outer side of the gradient coil.

The radially outer side refers to a side of the gradient coil body 100 away from the central axis of the gradient coil.

In some embodiments of the present disclosure, the gradient coil undergoes harsh process environments such as vacuum and high temperature during a curing stage, and the internal epoxy resin (especially in a central area near the central axis of the gradient coil) will generate significant shrinkage stress and thermal stress during the curing process. By setting the sensors at the radially outer side, the sensors may be kept away from a core area of stress concentration, thereby effectively avoiding sensor damage, displacement, or performance drift caused by the above stresses during an encapsulation process, and minimizing potential risks brought by a manufacturing process.

FIG. 3 is an encapsulation schematic diagram of a non-metallic encapsulation device according to some embodiments of the present disclosure.

The gradient coil is introduced high-frequency alternating current during operating, which generates a changing Lorentz force. A changing temperature field also appears around the gradient coil, which makes temperature compensation necessary during a strain testing. Due to the particularity of magnetic resonance devices, a sensor encapsulation for temperature compensation cannot use metal materials, because the metal materials have special electromagnetic properties in the magnetic field and are likely to cause interference to the magnetic field of the magnetic resonance device. Metal encapsulation may introduce additional magnetic field noise, affecting the clarity and accuracy of magnetic resonance imaging. The metal encapsulation may also cause uneven distribution of the magnetic field, further affecting imaging quality. Therefore, to avoid electromagnetic interference, a specially customized non-metallic encapsulation device is configured to encapsulate the temperature sensor 300.

In some embodiments, as shown in FIG. 3, the temperature sensor 300 of each of the at least one sensor group of the gradient coil includes a non-metallic encapsulation 500, and the temperature sensor 300 is encapsulated within the non-metallic encapsulation 500.

The non-metallic encapsulation 500 refers to an encapsulation manner that uses non-metallic materials as a shell to protect the temperature sensor 300.

In some embodiments, to achieve accurate temperature measurement, the non-metallic encapsulation device needs to have good thermal conductivity.

In some embodiments, the non-metallic encapsulation 500 may be made of non-metallic materials, and the non-metallic materials may include ceramic, graphite, carbon fiber composite materials, etc. Since some non-metallic materials (such as graphite and carbon fiber composite materials) are electrically conductive and may short-circuit the gradient coil, an insulating treatment is therefore required.

In some embodiments, the non-metallic encapsulation 500 may be a ceramic tube. Ceramic not only has excellent electrical insulation and high temperature resistance, but also has high thermal conductivity, which enables the ceramic tube to effectively protect the temperature sensor 300 from the external environment while ensuring the stability of the sensor under extreme temperature conditions. The good thermal conductivity of ceramic helps to quickly transfer heat to the temperature sensor 300, thereby avoiding measurement inaccuracy due to thermal imbalance. In addition, ceramic has excellent chemical stability and corrosion resistance, which can significantly extend a service life of the temperature sensor 300, especially in harsh environments.

In some embodiments, as shown in FIG. 3, the non-metallic encapsulation 500 includes a cavity 501 and an aperture 502. An optical fiber 400 connected with the temperature sensor 300 passes through the aperture 502. One end of the temperature sensor 300 is fixed (e.g., fixed within the aperture), and the other end of the temperature sensor 300 is disposed within the cavity 501.

The cavity 501 refers to an empty space formed in a structure of the non-metallic encapsulation 500. In some embodiments, the cavity 501 may be configured to accommodate and protect the temperature sensor 300, and provide necessary physical isolation and support.

The aperture 502 refers to a channel or hole opened inside of the non-metallic encapsulation 500. In some embodiments, the aperture 502 may be configured to allow the optical fiber to pass through and connect different parts inside and outside the non-metallic encapsulation 500.

In some embodiments, as shown in FIG. 3, one end of the temperature sensor 300 is fixed within the aperture 502, and the other end is disposed within the cavity 501. When the temperature changes, the end of the temperature sensor 300 within the cavity 501 will, due to thermal expansion or thermo-optic effect of the fiber grating sensor, cause the central wavelength offset of the reflected light to achieve temperature change measurement.

In some embodiments, when the non-metallic encapsulation 500 uses the ceramic tube, an inside of the ceramic tube is provided with the cavity 501, and one end has a small aperture 502, a diameter of the small aperture 502 is just enough for the optical fiber 400 of the temperature sensor 300 to pass through. A grid area 700 of the temperature sensor 300 passes through the aperture 502 and is completely placed inside the ceramic tube, and then the optical fiber is fixed at the aperture 502 with high-temperature adhesive, ensuring that the temperature sensor 300 includes one end fixed and one end free within the ceramic encapsulation.

The free end may freely stretch and contract with temperature changes. As the temperature changes, a grating pitch of the fiber grating sensor will also change accordingly, causing the central wavelength offset of the reflected light, thereby achieving accurate measurement of temperature changes. A design of the fixed end effectively limits excessive movement of the fiber grating sensor during temperature changes, ensuring measurement stability.

In some embodiments, as shown in FIG. 3, an optical fiber outlet end may be protected using a heat shrink tube 800.

In some embodiments of the present disclosure, the grid area 700 of the temperature sensor 300 has one end fixed, while the other end moves relatively freely within the cavity 501, forming a suspended structure with one end fixed and one end free, while isolating the transmission of external mechanical strain, significantly reducing the interference of external strain on the grating pitch change of the fiber grating sensor, thereby ensuring the accuracy of temperature measurement. The design enables the temperature sensor 300 to accurately reflect actual temperature changes and can be configured to perform temperature compensation for the strain sensor 200 to accurately determine the strain at the predetermined position.

In some embodiments, a ratio of a diameter of the cavity 501 to a diameter of the temperature sensor 300 is greater than 10.

The diameter of the cavity 501 refers to a maximum straight-line distance on a cross-section perpendicular to a central axis of the non-metallic encapsulation 500 (e.g., a cross-section of the cavity 501). The diameter of the temperature sensor 300 refers to a diameter of the optical fiber 400 of the temperature sensor 300.

In some embodiments, the larger the ratio of the diameter of the cavity 501 to the diameter of the temperature sensor 300, the larger gap between the cavity 501 and the temperature sensor 300, which makes the temperature sensor 300 less affected by the deformation of the ceramic tube, thereby reducing the risk of sensor damage.

In some embodiments of the present disclosure, the ratio of the diameter of the cavity 501 to the diameter of the temperature sensor 300 is greater than 10, thereby ensuring that the free end of the temperature sensor 300 is not squeezed or deformed due to the deformation of the ceramic tube.

In some embodiments, the temperature sensor 300 includes the non-metallic encapsulation 500, and the temperature sensor 300 is encapsulated within the non-metallic encapsulation 500. Such a design enables the temperature sensor 300 to accurately perceive temperature changes while effectively isolating the transmission of external mechanical strain. Since the encapsulation structure of the temperature sensor 300 can avoid the influence of strain on the temperature sensor 300, not only the accuracy of temperature measurement is improved, but also the accuracy of strain measurement is improved.

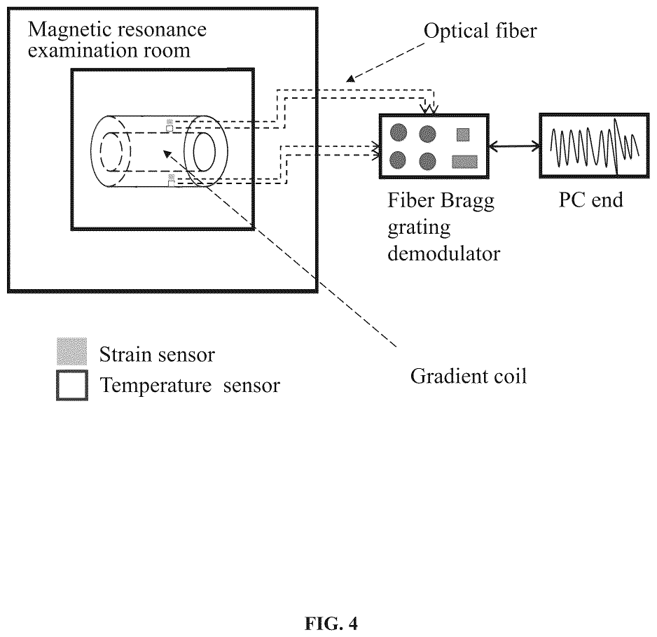

FIG. 4 is a structural schematic diagram of a monitoring system for a magnetic resonance gradient coil according to some embodiments of the present disclosure.

In some embodiments, a monitoring system for a magnetic resonance gradient coil includes at least one sensor group, a fiber grating demodulator, and an electronic device. Each sensor group is disposed at a predetermined position on a gradient coil body. Each sensor group includes a strain sensor configured to detect a strain signal at the predetermined position and a temperature sensor configured to detect a temperature signal at the predetermined position. The fiber grating demodulator is connected to the at least one sensor group via optical fibers and configured to demodulate the strain signal and the temperature signal from each of the at least one sensor group. The electronic device is connected to the fiber grating demodulator and configured to determine a strain of the gradient coil body at the predetermined position based on the demodulated strain signal and the demodulated temperature signal from each of the at least one sensor group.

In some embodiments, a monitoring system for a magnetic resonance gradient coil includes at least one fiber grating sensor and a fiber grating demodulator. The electronic device is integrated into the fiber grating demodulator. Thus, the fiber grating demodulator is configured to determine a variation of a physical quantity (e.g., a strain, a temperature, a vibration or an acceleration, etc.) of the gradient coil body at the predetermined position based on a detected signal of the at least one fiber grating sensor. For example, the fiber grating demodulator is configured to both demodulate the detected signal (e.g., the strain signal, the temperature signal, the acceleration, etc.) from each of the at least one fiber grating sensor and determine the physical quantity variation of the gradient coil body based on the detected signal.

For more content on the sensor group, the predetermined position, the strain sensor, the temperature sensor, the temperature signal, the fiber grating demodulator, and the optical fiber, refer to FIG. 1 and its related description.

In some embodiments, as shown in FIG. 4, the monitoring system for the magnetic resonance gradient coil includes the gradient coil of the magnetic resonance device, the fiber grating demodulator, and an electronic device.

In some embodiments, the electronic device may be a personal computer (PC) terminal, and software programs are installed on the PC terminal.

In some embodiments, the PC terminal is configured to control the fiber grating demodulator and process the measured change values of strain or temperature.

In some embodiments, the PC terminal may output the strain through a display screen, or output the strain through email or message.

In some embodiments, the fiber grating demodulator is connected to the strain sensor and the temperature sensor in the gradient coil of the magnetic resonance device through the optical fiber, and the electronic device is connected to the fiber grating demodulator.

In some embodiments, the magnetic resonance device is located in a magnetic resonance examination room, the fiber grating demodulator and the PC terminal are located outside the magnetic resonance examination room. In some embodiments, the magnetic resonance device and the fiber grating demodulator are located in the magnetic resonance examination room, and the PC terminal is located outside the magnetic resonance examination room. In some embodiments, the magnetic resonance device, the fiber grating demodulator, and the PC terminal are all located in the magnetic resonance examination room.

In some embodiments, a connection between the electronic device and the fiber grating demodulator may be wired or wireless.

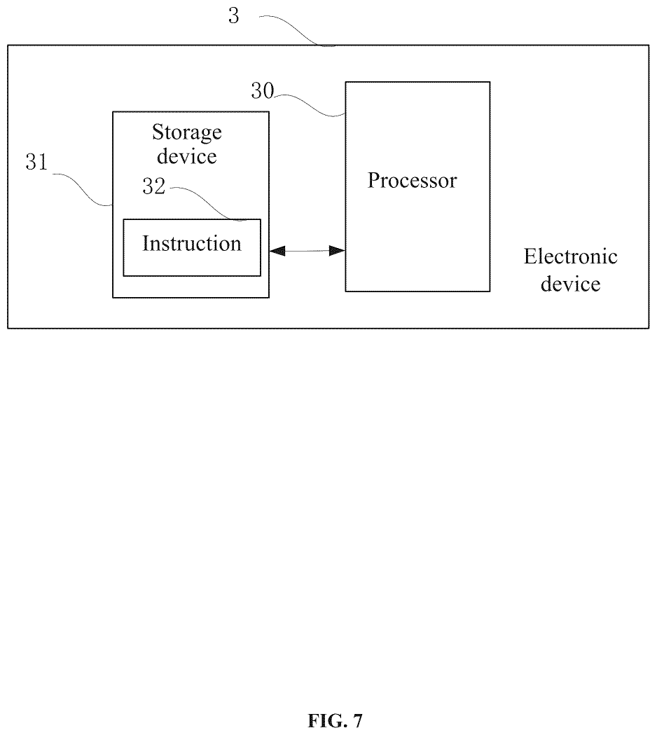

For more content on the electronic device, refer to FIG. 7 and its related description.

In some embodiments, the fiber grating demodulator is connected to the at least one sensor group via the optical fiber and is configured to demodulate the strain signal and the temperature signal from each of the at least one sensor group.

In some embodiments, the temperature sensor and the strain sensor are both fiber grating sensors.

A principle of the fiber grating sensor may be simply explained as: based on a periodic modulation of a refractive index of the fiber core, when a beam of light is incident on the fiber grating sensor, only light waves with wavelengths satisfying a Bragg condition will be reflected. By measuring a relative light intensity of the reflected signal, a central wavelength of the relative light of the fiber grating sensor may be obtained. External temperature and stress cause the central wavelength of the fiber grating sensor to shift by affecting an effective refractive index and a grating period of the fiber grating sensor.

In some embodiments, the temperature signal includes a first central wavelength offset, the strain signal includes a second central wavelength offset, and the strain of the gradient coil body at the predetermined position is determined based on a difference between the first central wavelength offset and the second central wavelength offset.

The first central wavelength offset refers to a central wavelength offset of the reflected light caused by thermal expansion or thermo-optic effect of the fiber Bragg grating measured by the fiber Bragg grating temperature sensor when the temperature changes.

In some embodiments, the influence of temperature on the central wavelength of the reflected light is mainly due to the thermo-optic effect and thermal expansion effect of the optical fiber material, that is, the change in temperature causes the effective refractive index of the fiber core and the grating period to change. Under the effect of only considering temperature influence, when the central wavelength of the reflected light of the fiber Bragg grating is affected by temperature, the central wavelength offset of the reflected light is shown as formula (1):

$$\frac{d {λ}_{B}}{{λ}_{B}} = ( α + β ) d T \qquad ( 1 )$$

In formula (1), λ_{B} represents the central wavelength of the reflected light of the fiber Bragg grating;

$$\frac{d {λ}_{B}}{{λ}_{B}}$$

represents the central wavelength offset of the reflected light. The central wavelength offset

$$\frac{d {λ}_{B}}{{λ}_{B}}$$

of the reflected light calculated oy formula (1) is a central wavelength offset of the reflected light considering only the influence of temperature. For example, the central wavelength offset

$$\frac{d {λ}_{B}}{{λ}_{B}}$$

is the first central wavelength offset. The first central wavelength offset

$$\frac{d {λ}_{B 1}}{{λ}_{B 1}}$$

is measured by the temperature sensor. A sum of α and β represents a temperature sensitivity coefficient of the fiber Bragg grating temperature sensor; and dT represents a temperature change value.

In some embodiments, the sum of α and β is a fixed value, which is determined by a grating writing process.

In some embodiments, from formula (1), it may be seen that the central wavelength offset

$$\frac{d {λ}_{B}}{{λ}_{B}}$$

of the reflected light has a linear relationship with the temperature change value dT.

In some embodiments, the strain is also one of the important factors affecting a central wavelength drift of the fiber Bragg grating. Whether the optical fiber is squeezed or stretched during work, it will directly cause the grating period to change, and the electrooptic effect of the optical fiber material will also change the effective refractive index of the fiber core. These two changes will cause the central wavelength of the grating reflection spectrum to drift. Without considering the influence of temperature on the fiber Bragg grating, an influence of an axial strain on the central wavelength of the reflected light is as shown in formula (2):

$$\frac{d {λ}_{B}}{{λ}_{B}} = ( 1 - {P}_{e} ) Δ ε \qquad ( 2 )$$

In formula (2), Pₑ is an effective electrooptic coefficient of the fiber Bragg grating, which is a constant related only to material coefficients; Δε is the axial strain of the fiber Bragg grating. The central wavelength offset

$$\frac{d {λ}_{B}}{{λ}_{B}}$$

of the reflected light calculated by formula (2) is a central wavelength offset of the reflected light considering only the influence of the axial strain, recorded as a third central wavelength offset, which may be denoted as

$$\frac{d {λ}_{B 3}}{{λ}_{B 3}} .$$

In some embodiments, from formula (2), it may be seen that the central wavelength offset of the reflected light has a linear relationship with the strain.

The second central wavelength offset refers to a central wavelength offset of the reflected light caused by the change in the grating pitch of the fiber Bragg grating collected by the strain sensor under the influence of external force and temperature.

When the gradient coil of the magnetic resonance device is working, the gradient coil is exactly in an environment with typical temperature-stress cross-sensitivity characteristics. When the gradient coil is working, the internal coils carry high-frequency alternating current, which generates the changing Lorentz force, and the changing temperature field also appears around the internal coils, and the strain sensor is directly embedded inside the epoxy resin, so the second central wavelength offset of the strain sensor is caused by the combined action of the temperature and the strain. This situation is also called a temperature-strain cross-sensitivity characteristic of the fiber Bragg grating in engineering.

In practical applications, the external temperature and the strain will jointly act on the fiber Bragg grating, and the grating period length and the refractive index will change with the external temperature and the strain. According to the relevant analysis of the above formula (1) and formula (2), the central wavelength offset of the reflected light has a good linear relationship with both the temperature and the strain. From the superposition property, when both act on a same fiber Bragg grating, the dependence of the central wavelength offset of the reflected light on the strain and the temperature may be described as shown in formula (3):

$$\frac{d {λ}_{B}}{{λ}_{B}} = ( α + β ) dT + ( 1 - {P}_{e} ) Δ ε \qquad ( 3 )$$

The central wavelength offset

$$\frac{d {λ}_{B}}{{λ}_{B}}$$

of the reflected light calculated by formula (3) is a central wavelength offset of the reflected light considering both the temperature and the axial strain influence. For example, the central wavelength offset is the second central wavelength offset, which may be denoted as

$$\frac{d {λ}_{B 2}}{{λ}_{B 2}} ,$$

and the second central wavelength offset

$$\frac{d {λ}_{B 2}}{{λ}_{B 2}}$$

is measured by the strain sensor.

In some embodiments, the second central wavelength offset measured by the strain sensor is a result of the combined action of the external temperature and the strain. Therefore, it is necessary to perform temperature compensation on the second central wavelength offset measured by the strain sensor to obtain a central wavelength offset caused only by the strain. That is, separate a part offset (e.g., the first central wavelength offset) caused by temperature change from the second central wavelength offset measured by the strain sensor, thereby obtaining a part offset (e.g., the third central wavelength offset) caused only by strain.

That is, the central wavelength offset (e.g., the third central wavelength offset) of the reflected light caused only by the strain at the predetermined position of the gradient coil bod is a difference between the second central wavelength offset measured by the strain sensor at the predetermined position and the first central wavelength offset measured by the temperature sensor. From the above formula and analysis:

$$\frac{d {λ}_{B 3}}{{λ}_{B 3}} = \frac{d {λ}_{B 2}}{{λ}_{B 2}} - \frac{d {λ}_{B 1}}{{λ}_{B 1}} = ( α + β ) dT + ( 1 - {P}_{e} ) Δ ε - ( α + β ) dT = ( 1 - {P}_{e} ) Δ ε$$

In some embodiments, by demodulating the central wavelength offset of the fiber Bragg grating and combining the formula (1) and formula (2), the change values of the external temperature and the strain may be demodulated. In addition, other physical quantities (such as a pressure and a displacement) may be derived by demodulating the central wavelength offset of the reflected light. In some embodiments, the demodulation process is performed by the fiber grating demodulator. That is, according to

$$\frac{d {λ}_{B 3}}{{λ}_{B 3}} = ( 1 - {P}_{e} ) Δ ε ,$$

the fiber grating demodulator may calculate the strain at the predetermined position based on the central wavelength offset (e.g., the third central wavelength

$$\frac{d {λ}_{B 3}}{{λ}_{B 3}} )$$

of the reflected light caused only by the strain at the predetermined position of the gradient coil body.

In some embodiments of the present disclosure, by arranging the temperature sensor and the strain sensor in the monitoring system for the magnetic resonance gradient coil, the deformation and the temperature change of the gradient coil during use can be monitored in real time. The system can effectively prevent the gradient coil from being affected by static failure, fatigue failure, and thermal fatigue, ensuring that the gradient coil maintains stable performance and reliability during operation. By combining the demodulation of the strain signal and the temperature signal, the strain data of the gradient coil body at the predetermined position can be accurately obtained, thereby achieving optimized monitoring and protection of the magnetic resonance device.

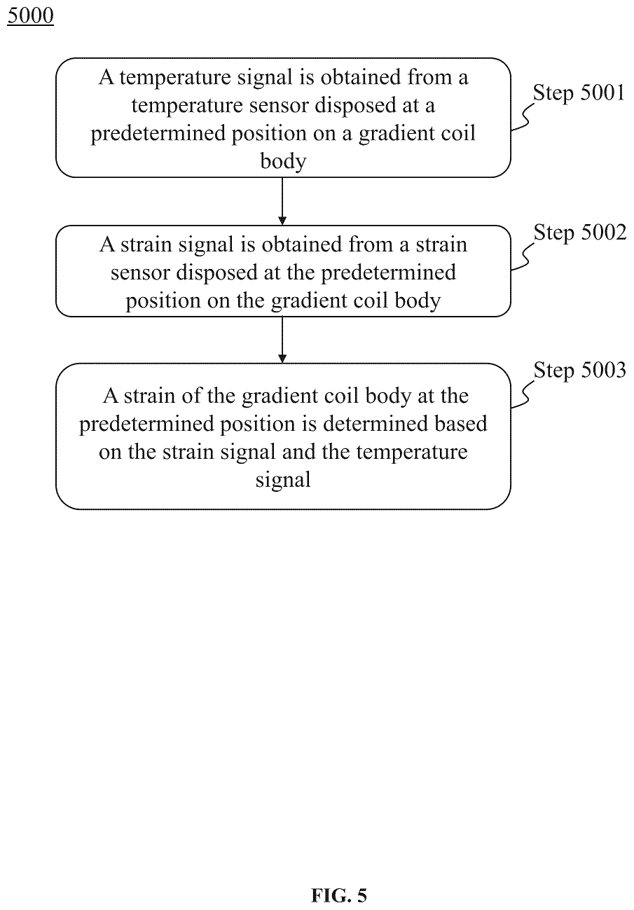

FIG. 5 is an exemplary flowchart of a monitoring method for a magnetic resonance gradient coil according to some embodiments of the present disclosure.

In some embodiments, as shown in FIG. 5, a process 5000 includes steps 5001-5003. In some embodiments, the process 5000 is performed by the monitoring system for the magnetic resonance gradient coil.

In 5001, a temperature signal is obtained from a temperature sensor disposed at a predetermined position on a gradient coil body.

In some embodiments, the temperature signal is measured by the temperature sensor and then demodulated by the fiber grating demodulator connected to the temperature sensor via an optical fiber.

In 5002, a strain signal is obtained from a strain sensor disposed at the predetermined position on the gradient coil body.

In some embodiments, the strain signal is measured by the strain sensor and then demodulated by the fiber grating demodulator connected to the strain sensor via an optical fiber.

For more content on the gradient coil body, the predetermined position, the temperature sensor, the strain sensor, the strain signal, the temperature signal, and the fiber grating demodulator, refer to FIG. 1 and its related description.

In 5003, a strain of the gradient coil body at the predetermined position is determined based on the strain signal and the temperature signal.

For more content on how to calculate the strain at the predetermined position, refer to FIG. 4 and its related description.

In some embodiments of the present disclosure, through the process 5000, the strain of the gradient coil body at the predetermined position can be calculated and output. Based on the strain data, technicians can monitor the operating state of the gradient coil in real time, promptly discover potential problems in the structure, such as crack formation, fatigue damage, or local overload, thereby providing reliable data support for maintenance, inspection, and fault warning, and improving the operating safety and reliability of the gradient coil.

It should be noted that the above description regarding process 5000 is only for exemplary and illustrative purposes and does not limit the applicable scope of the present disclosure. For those skilled in the art, under the guidance of the present disclosure, various modifications and changes may be made to process 5000. However, these modifications and changes are still within the scope of the present disclosure.

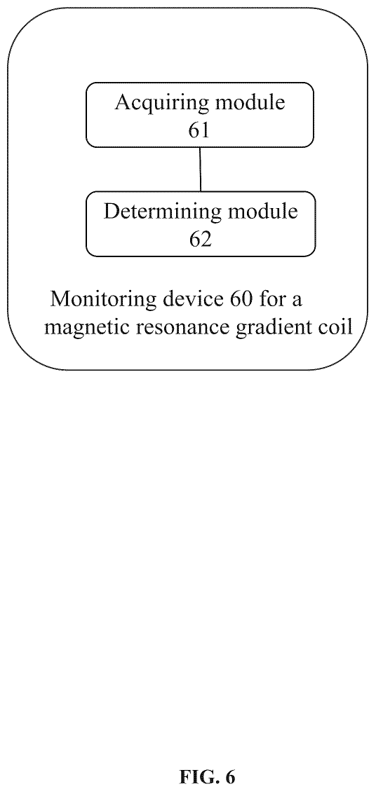

FIG. 6 is a structural schematic diagram of a monitoring device for a magnetic resonance gradient coil according to some embodiments of the present disclosure.

In some embodiments, as shown in FIG. 6, a monitoring device 60 for a magnetic resonance gradient coil includes an acquiring module 61 and a determining module 62.

The acquiring module 61 is a module for obtaining a temperature signal from a temperature sensor and a strain signal from a strain sensor at a predetermined position, respectively.

In some embodiments, the acquiring module 61 is configured to obtain, from a temperature sensor disposed at a predetermined position on a gradient coil body, a temperature signal. The acquiring module 61 is configured to obtain, from a strain sensor disposed at the predetermined position on the gradient coil body, a strain signal.

The determining module 62 refers to a module for determining the strain at the predetermined position.

In some embodiments, the determining module 62 may determine the strain of the gradient coil body at the predetermined position based on the strain signal and the temperature signal.

In some embodiments, the acquiring module 61 and the determining module 62 may be implemented by a processor in a computer device. In some embodiments, the acquiring module 61 and the determining module 62 may also be implemented by specific logic circuits. In some embodiments, the processor may be a central processing unit (CPU), a microprocessor (MPU), a digital signal processor (DSP), or a field programmable gate array (FPGA), etc.

It should be noted that the information interaction, execution process, etc. between the above-mentioned devices/units, since they are based on the same concept as the method embodiments of the present disclosure, their specific functions and technical effects can be referred to the manner embodiment part, and will not be repeated here.

In addition, the monitoring device 60 may be a software unit, a hardware unit, or a unit combining software and hardware, and may be integrated into the electronic device as an independent attachment, or may exist as an independent terminal device.

Those skilled in the art can clearly understand that for the convenience and conciseness of description, only the division of the above functional units and modules is used as an example. In practical applications, the above functions may be allocated to different functional units and modules as needed; that is, the internal structure of the device is divided into different functional units or modules to complete all or part of the functions described above. The functional units and modules in the embodiments may be integrated into one processing unit, or each unit may exist physically alone, or two or more units may be integrated into one unit. The above integrated units may be implemented in the form of hardware or software functional units. In addition, the specific names of the functional units and modules are only for the convenience of distinguishing each other and are not configured to limit the protection scope of the present disclosure. For the specific working process of the units and modules in the above system, reference may be made to the corresponding process in the foregoing method embodiments, and details are not repeated here.

FIG. 7 is a structural schematic diagram of an electronic device according to some embodiments of the present disclosure.

In some embodiments, as shown in FIG. 7, an electronic device 3 includes at least one storage device 31 including a set of instructions 32 and at least one processor 30 in communication with the at least one storage device 31. When executing the set of instructions, the at least one processor is directed to cause the electronic device to perform the monitoring method for the magnetic resonance gradient coil.

The storage device 31 is a hardware or a medium for storing the relevant data and results of the monitoring method.

In some embodiments, the at least one storage device 31 includes the set of instructions 32. The set of instructions 32 may be divided into one or more modules/units, and the one or more modules/units are stored in the at least one storage device 31 and executed by the at least one processor 30 to complete the embodiments of the present disclosure. The one or more modules/units may be instruction segments of an instruction that may complete specific functions, and the instruction segments are configured to describe an execution process of the set of instructions 32 in the electronic device 3.

In some embodiments, the at least one storage device 31 contains a computer program that may run on the at least one processor 30. When the at least one processor 30 executes the computer program, it implements the steps in any of the method embodiments, or when the at least one processor 30 executes the computer program, it implements the functions of each module/unit in the above system embodiments.

In some embodiments, the computer program may be divided into one or more modules/units, and the one or more modules/units are stored in the at least one storage device 31 and executed by the at least one processor 30 to complete the present disclosure. The one or more modules/units may be a series of computer program instruction segments that may complete specific functions, and the instruction segments are configured to describe the execution process of the computer program in the electronic device 3.

The at least one processor 30 refers to a device that performs data processing, calculation, and decision-making.

In some embodiments, the at least one processor 30 may include a central processing unit (CPU), an application-specific integrated circuit (ASIC), an application-specific instruction processor (ASIP), etc., or any combination thereof.

In some embodiments, the present disclosure provides a computer program product, when the computer program product runs on the electronic device 3, it causes the electronic device 3 to implement the steps in the above various method embodiments when executed.

If the integrated unit is implemented in the form of a software functional unit and sold or used as an independent product, it may be stored in a computer-readable storage medium. Based on such an understanding, the present disclosure implements all or part of the processes in the above method embodiments, which may be completed by instructing relevant hardware through the computer program. The computer program may be stored in a computer-readable storage medium, and when the computer program is executed by the at least one processor 30, the steps of the above various method embodiments may be implemented. Among them, the computer program includes computer program code, which may be in the form of source code, object code, executable file, or some intermediate form. The computer-readable medium may at least include: any entity or device that may carry the computer program code to a terminal, recording medium, computer memory, read-only memory (ROM), random access memory (RAM), electrical carrier signal, telecommunication signal, and software distribution medium, e.g., U disk, a mobile hard disk, a magnetic disk, an optical disk, etc. In some jurisdictions, according to legislation and patent practice, the computer-readable medium cannot be electrical carrier signals and telecommunication signals.

In the above embodiments, the description of each embodiment has its own focus. For parts not described or recorded in detail in a certain embodiment, reference may be made to the relevant description of other embodiments.

Those of ordinary skill in the art may realize that the units and algorithm steps of each example described in combination with the embodiments disclosed herein may be implemented by electronic hardware, or a combination of computer software and electronic hardware. Whether these functions are executed in hardware or software depends on the specific application and design constraints of the technical solution. Professionals and technicians may use different manners for each specific application to implement the described functions, but such implementation should not be considered beyond the scope of the present disclosure.

In some embodiments provided in the present disclosure, it should be understood that the disclosed device/network device and method may be implemented in other ways. For example, the device/network device embodiments described above are only illustrative. For example, the division of modules or units is only a logical function division, and there may be other divisions in actual implementation, for example, a plurality of units or components may be combined or integrated into another system, or some features may be ignored or not executed. In addition, the mutual coupling or direct coupling or communication connection shown or discussed may be through some interfaces, indirect coupling or communication connection of devices or units, which may be electrical, mechanical, or other forms.

The units described as separate components may or may not be physically separated, and the components displayed as units may or may not be physical units; that is, they may be located in one place or may be distributed on a plurality of network units. Some or all of the units may be selected according to actual needs to achieve the purpose of the solution of the embodiment.

What is claimed is:

1. A gradient coil for a magnetic resonance device, comprising:
a gradient coil body; and
at least one sensor group, wherein
each of the at least one sensor group is disposed at a predetermined position on the gradient coil body,
each sensor group includes a strain sensor configured to detect a strain signal at the predetermined position and a temperature sensor configured to detect a temperature signal at the predetermined position.

2. The gradient coil according to claim 1, wherein the strain sensor of each of the at least one sensor group is arranged along an axial direction of the gradient coil.

3. The gradient coil according to claim 1, wherein the strain sensor of each of the at least one sensor group is arranged along a circumferential direction of the gradient coil.

4. The gradient coil according to claim 1, wherein the temperature sensor of each of the at least one sensor group comprises a non-metallic encapsulation, and the temperature sensor is encapsulated within the non-metallic encapsulation.

5. The gradient coil according to claim 4, wherein the non-metallic encapsulation comprises a cavity and an aperture, an optical fiber connected with the temperature sensor passes through the aperture, one end of the temperature sensor is fixed, and the other end of the temperature sensor is disposed within the cavity.

6. The gradient coil according to claim 5, wherein a ratio of a diameter of the cavity to a diameter of the temperature sensor is greater than 10.

7. The gradient coil according to claim 4, wherein the non-metallic encapsulation is a ceramic tube.

8. The gradient coil according to claim 1, wherein the strain sensor and the temperature sensor of each of the at least one sensor group are disposed on a same optical fiber.

9. The gradient coil according to claim 1, wherein the strain sensor and the temperature sensor of each of the at least one sensor group are disposed on different optical fibers.

10. The gradient coil according to claim 1, wherein the strain sensor or the temperature sensor is a fiber grating sensor.

11. The gradient coil according to claim 1, wherein the predetermined position is a position on the gradient coil where a strain gradient and/or a temperature gradient meets a predetermined condition.

12. The gradient coil according to claim 4, wherein the strain sensor and the temperature sensor of each of the at least one sensor group are embedded at the predetermined position and integrated with the gradient coil body within an epoxy resin.

13. The gradient coil according to claim 1, further comprising optical fibers connected to each of the at least one sensor group, wherein one end of each optical fiber is connected to the sensor group and the other end of each optical fiber is connected to a fiber grating demodulator.

14. The gradient coil according to claim 1, further comprising an acceleration sensor configured to detect vibrations of the gradient coil.

15. The gradient coil according to claim 1, wherein the temperature sensor and the strain sensor of each of the at least one sensor group are located at a radially outer side of the gradient coil.

16. A monitoring system for a magnetic resonance gradient coil, comprising:
at least one fiber grating sensor, wherein each fiber grating sensor is disposed at a predetermined position on a gradient coil body; and
a fiber grating demodulator, connected to the at least one fiber grating sensor via optical fibers, and configured to determine a variation of a physical quantity of the gradient coil body at the predetermined position based on a detected signal of the at least one fiber grating sensor.

17. The monitoring system of claim 16, wherein the at least one fiber grating sensor includes a strain sensor configured to detect a strain signal at the predetermined position and a temperature sensor configured to detect a temperature signal at the predetermined position, and the fiber grating demodulator is configured to determine a strain of the gradient coil body at the predetermined position based on the strain signal and the temperature signal.

18. The monitoring system of claim 16, wherein the physical quantity includes at least one of: a strain, a temperature, a vibration, or an acceleration.

19. The monitoring system of claim 17, wherein the temperature signal includes a first central wavelength offset, the strain signal includes a second central wavelength offset, and the strain of the gradient coil body at the predetermined position is determined based on a difference between the first central wavelength offset and the second central wavelength offset.

20. A monitoring method for a magnetic resonance gradient coil, comprising:
obtaining, from a temperature sensor disposed at a predetermined position on a gradient coil body, a temperature signal;
obtaining, from a strain sensor disposed at the predetermined position on the gradient coil body, a strain signal; and
determining a strain of the gradient coil body at the predetermined position based on the strain signal and the temperature signal.
